(19) United States
(12) Patent Application Publication
(10) Pub. No.: US 2024/0060173 A1
(43) Pub. Date: Feb. 22, 2024

(54) SYSTEM FOR PROCESSING SEMICONDUCTOR DEVICE, METHOD FOR FORMING SEMICONDUCTOR DEVICE, AND METHOD FOR FORMING PROTECTIVE STRUCTURE ON CHAMBER

(71) Applicant: Taiwan Semiconductor Manufacturing Company, Ltd., Hsinchu (TW)

(72) Inventors: Ren-Guan DUAN, Hsinchu City (TW); Chen-Hsiang LU, Hsinchu City (TW); Tien-Chih CHENG, Hsinchu City (TW); Clinton K. LIEN, Taichung City (TW)

(21) Appl. No.: 17/819,982

(22) Filed: Aug. 16, 2022

(51) Int. Cl. C23C 16/02; C23C 16/458; C23C 16/455; C23C 16/40

(52) U.S. Cl. CPC C23C 16/0272; C23C 16/4583; C23C 16/45536; C23C 16/403; C23C 16/405

(57) ABSTRACT

A system for processing a semiconductor device is provided. The system includes a chamber, a carrier disposed in the chamber and configured to holding a substrate, and a protective structure disposed on the chamber. The protective structure includes a first protective layer disposed on a surface of the chamber and a second protective layer disposed on the first protective layer. The first protective layer is amorphous. The second protective layer is crystalline.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers over a semiconductor substrate, and patterning the various material layers using lithography and etching processes to form circuit components and elements thereon. Many integrated circuits (ICs) are typically manufactured on a single semiconductor wafer, and individual dies on the wafer are singulated by sawing between the integrated circuits along a scribe line. The individual dies are typically packaged separately, in multi-chip modules, for example, or in other types of packaging.

The semiconductor dies are processed in various chambers in different steps. The chamber provides a controlled environment for the process, such as temperature and pressure, and the chamber needs to withstand for the reactant during the process. Although existing chambers have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a system for processing a semiconductor device in accordance with some embodiments.

FIG. 2A is a schematic view of an etching system in some embodiments.

FIG. 2B is a schematic view of a deposition system in some embodiments.

FIG. 3 shows detail of the protective structure in some embodiments.

FIG. 4 is a schematic view when two units of the chamber assembled with each other in some embodiments.

FIG. 5A is an enlarged view of a region in FIG. 1, in accordance with some embodiments of the present disclosure.

FIG. 5B is an enlarged view of a region in FIG. 1, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

Furthermore, the phrase “in a range between a first value and a second value” or “in a range from a first value to a second value” indicates that the range includes the first value, the second value, and other values between them.

A method for forming a protective structure on a chamber and using the chamber to process a semiconductor device are provided in some embodiments. The protective structure includes different protective layers, and they are formed by atomic layer deposition (ALD) to increase the erosion resistance of the protective structure, adhesive strength between the chamber and the protective structure, and the micro-roughness on the surface of the protective structure, in accordance with some embodiments of the present disclosure.

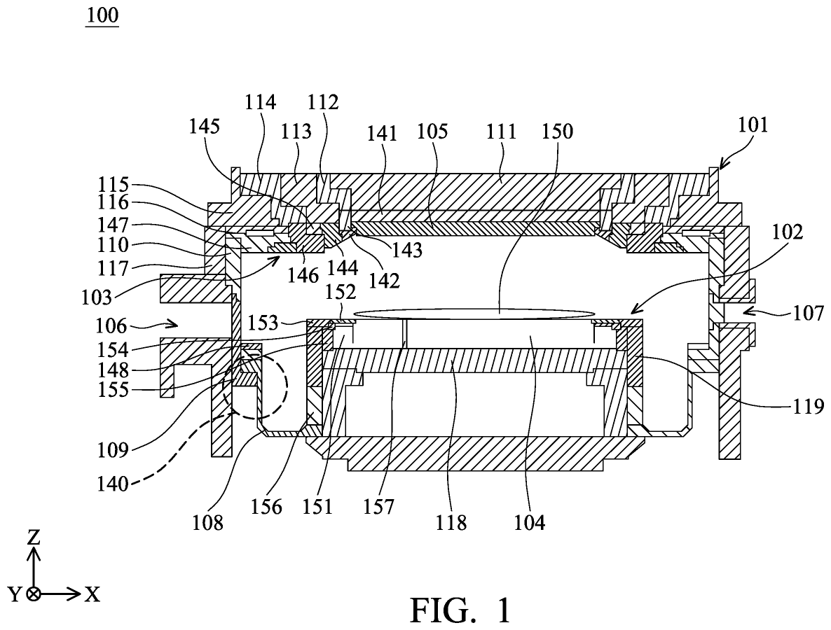

FIG. 1 illustrates a cross-sectional view of a system 100 for processing a semiconductor device in accordance with some embodiments. In some embodiments, the system 100 includes a chamber 101, which may be a vacuum chamber. In some embodiments, the system 100 includes a lower stage 102 (e.g. a carrier 102) and an upper stage 103 within the chamber 101. In some embodiments, the lower stage 102 may include a chuck 104 below the chuck. In some embodiments, the chuck 104 may be an electrostatic chuck (ESC). In some embodiments, the chuck may be a vacuum chuck, or the like. In some embodiments, a substrate 150 to be processed is placed on and secured by the chuck. In some embodiments, the upper stage 103 includes an inner center electrode 105. In some embodiments, the inner center electrode 105 overlaps the substrate 150, and the inner center electrode 105 may have an area at least equal to or larger than the substrate 150. In some embodiments, the inner center electrode 105 has a circular shape in a plan view.

In some embodiments, the chamber 101 includes at least one gas-feeding port 106 connected to at least one gas supply line (not shown), and at least one vacuum port 107 connected to a pressure control unit, e.g., a pump and a pressure gauge. In some embodiments, the pressure control unit is able to provide an environment in the chamber 101 with a pressure of a few millitorr (mTorr) to a few Torr. In some embodiments, gas through the at least one gas-feeding port 106 to the chamber 101 may include at least one or a combination of O₂, Ar, N₂, H₂, NH₃, N₂O, CF₄, SF₆, CCl₄, CH₄, H₂S, SiH₄, metal-containing precursors, etc. For example, process gas (e.g., Ar) is added to the chamber 101 through the at least one gas-feeding port 106 and pumped out by a pump through the at least one vacuum port 107, in accordance with some embodiments of the present disclosure.

In some embodiments, the chamber 101 may further include a exhaust plate 108, a second casing 109, and a third casing 110. In some embodiments, the exhaust plate 108, the second casing 109, and the third casing 110 may be assembled to form side and bottom portions of the chamber 101. In some embodiments, the second casing 109 may be disposed between the exhaust plate 108 and the third casing 110. In some embodiments, the exhaust plate 108 and the second casing 109 may arrange in the XY plane, and may arrange in the Z direction. In some embodiments, the second casing 109 and the third casing 110 may be arranged in the Z direction.

In some embodiments, the chamber 101 may further include an inner upper electrode 111, a separator 112, an outer upper electrode 113, an outer insulator 114, a first top element 115, a upper deposition element 116, a second top element 117, a diffusion element 141, an inner quartz 142, an in-center electrode 143, an outer center electrode 144, an out-center electrode 145, an outer quartz 146, a grounding element 147, and a cover quartz 148. In some embodiments, the inner upper electrode 111 may be surrounded by the separator 112, the separator 112 may be surrounded by the outer upper electrode 113, the outer upper electrode 113 may be surrounded by the outer insulator 114, and the outer insulator 114 may be surrounded by the first top element 115. In some embodiments, the upper deposition element 116 may be disposed under the outer insulator 114 and the first top element 115. In some embodiments, the second top element 117 may surround the third casing 110 and the upper deposition element 116. The exhaust plate 108, the second casing 109, the third casing 110, the inner upper electrode 111, the separator 112, the outer upper electrode 113, the outer insulator 114, the first top element 115, the upper deposition element 116, or the second top element 117 may include a ground ring, a gas distribution plate (GDP), and an exhaust plate, in accordance with some embodiments of the present disclosure.

In some embodiments, the diffusion element 141 may be disposed between the inner center electrode 105 and the inner upper electrode 111. In some embodiments, the in-center electrode 143 may be disposed between the separator 112 and the inner quartz 142, and the diffusion element 141 may be in contact with the in-center electrode 143. In some embodiments, the outer center electrode 144 may be in contact with the outer upper electrode 113, the inner quartz 142, and the in-center electrode 143. In some embodiments, the out-center electrode 145 may be disposed below the outer upper electrode 113, and in contact with the outer center electrode 144. In some embodiments, the outer quartz 146 may be in contact with the outer insulator 114, the outer center electrode 144, and the out-center electrode 145. In some embodiments, the grounding element 147 may be disposed below the upper deposition element 116. In some embodiments, the cover quartz 148 may be disposed on the exhaust plate 108.

In some embodiments, the lower stage 102 may include a bottom plate 118 below the chuck. In some embodiments, the lower stage 102 may further include an outer liner 119, an anodization base 151, a cover ring 152, a shadow ring 153, an edge ring 154, an inner liner 155, a bottom liner 156, and a lift pin 157. In some embodiments, the chuck 104 may be surrounded by the outer liner 119, the anodization base 151, the cover ring 152, the shadow ring 153, the edge ring 154, and the inner liner 155. In some embodiments, the cover ring 152 may be disposed on the anodization base 151. In some embodiments, the shadow ring 153 may be adjacent to the cover ring 152. In some embodiments, the edge ring 154 may be disposed below the cover ring 152. In some embodiments, the inner liner 155 may be disposed under the shadow ring 153. In some embodiments, the bottom liner 156 may be disposed under the outer liner 119. In some embodiments, the lift pin 157 may be disposed in the chuck 104 and used for lifting the substrate 150.

In some embodiments, the substrate 150 may be a bulk silicon substrate although other semiconductor materials including group III, group IV, and group V elements may also be used. Alternatively, the substrate 150 may be a silicon-on-insulator (SOI) substrate in some embodiments. Generally, an SOI substrate includes a layer of a semiconductor material, such as silicon, formed on an insulator layer in some embodiments. The insulator layer may be, for example, a buried oxide (BOX) layer or a silicon oxide layer in some embodiments. In some embodiments, the insulator layer is provided on a substrate, such as a silicon or glass substrate. Alternatively, the substrate 150 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used in some embodiments.

In some embodiments, a device layer may be a polysilicon layer disposed on a substrate (not shown) for the formation of one or more polysilicon gates in the substrate 150. In some embodiments, the device layer may be a metallization layer such as an inter-layer dielectric (ILD) or an inter-metal dielectric layer (IMD) for forming interconnect structures (e.g., metal lines and/or vias). In some embodiments, the ILD layer and the IMD layers may include low-k dielectric materials having k values, for example, lower than about 4.0 or even 2.0 disposed between such conductive features. In some embodiments, the ILD layer and IMD layers may be made of, for example, phosphosilicate glass (PSG), borophosphosilicate glass (BPSG), fluorosilicate glass (FSG), SiOxCy, Spin-On-Glass, Spin-On-Polymers, silicon carbon material, compounds thereof, composites thereof, combinations thereof, or the like, formed by any suitable method, such as spin-on coating, chemical vapor deposition (CVD), plasma-enhanced CVD (PECVD), or the like.

In some embodiments, the device layer may be any layer in the substrate 150 that may be patterned using photolithography and etching processes. In some embodiments, the substrate 150 may include numerous device layers. Furthermore, the device layer may include a buffer layer (e.g., an oxide interfacial layer, not shown), an etch stop layer (e.g., a silicon nitride layer, a silicon carbide layer, or the like), or the like in some embodiments. In some embodiments, the etch stop layer may include one or more layers of dielectric materials. In some embodiments, suitable dielectric materials may include oxides (such as silicon oxide, aluminum oxide, or the like), nitrides (such as SiN, or the like), oxynitrides (such as SiON, or the like), oxycarbides (such as SiOC, or the like), carbonitrides (such as SiCN, or the like), combinations thereof, or the like, and may be formed using spin-on coating, CVD, PECVD, atomic layer deposition (ALD), a combination thereof, or the like. In some embodiments, a hard mask may be formed over the device layer for use as a patterning mask. In some embodiments, the hard mask may comprise an oxide, silicon oxynitride (SiON), silicon nitride (Si₃N₄), titanium nitride (TiN), or the like.

In some embodiments, one or more active and/or passive devices may be formed on the substrate 150. In some embodiments, the one or more active and/or passive devices may include various N-type metal-oxide semiconductor (NMOS) and/or P-type metal-oxide semiconductor (PMOS) devices, such as transistors, capacitors, resistors, diodes, photo-diodes, fuses, and the like. One of ordinary skill in the art will appreciate that the above examples are provided for the purpose of illustration only and are not meant to limit the present disclosure in any manner. Other circuitry may be also used as appropriate for a given application.

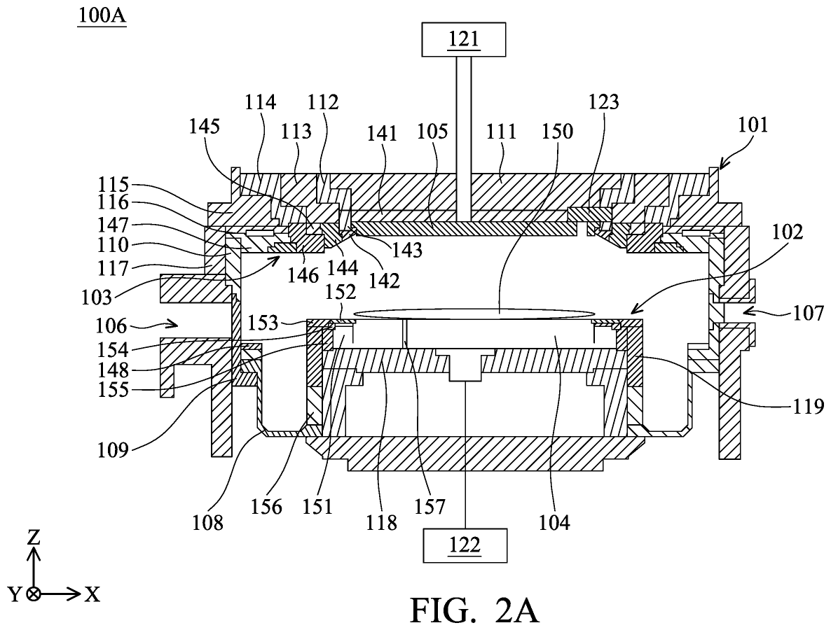

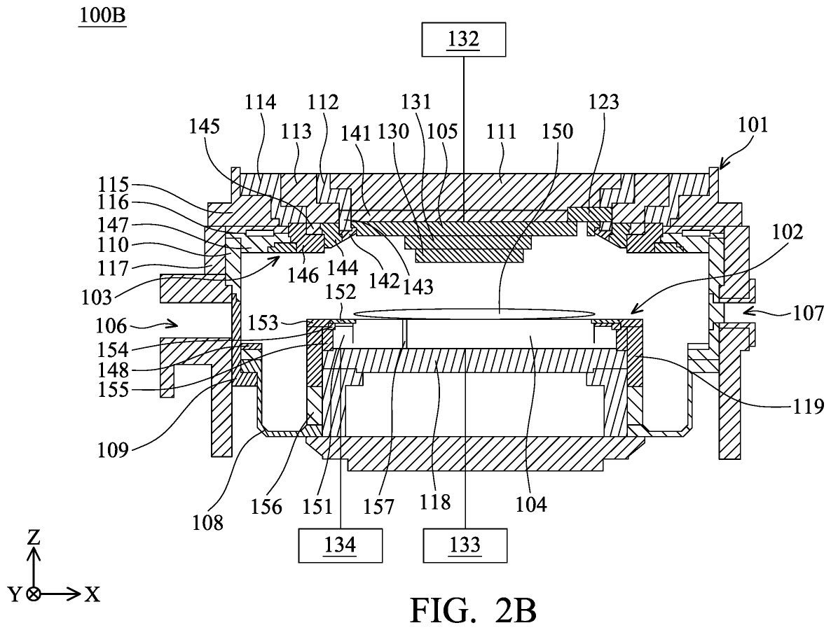

In some embodiments, additional elements may be provided in the chamber 101, so the system 100 may be applicable for different applications, such as lithography, etching, deposition, etc. For example, FIG. 2A is a schematic view of an etching system 100A in some embodiments. In some embodiments, the etching system 100A further includes a gas supply system 121 and a radio frequency (RF) system 122. In some embodiments, the gas supply system 121 is connected the upper stage 103 and is configured to introduce a desired process gas mixture into the space between the inner center electrode 105 and the substrate 150. In some embodiments, the RF system 122 is coupled to the bottom plate 117 of the lower stage 103 is configured to generate plasma in the space between the inner center electrode 105 and the substrate 150 from the process gas mixture provided by the gas supply system 121.

In some embodiments, the etching system 100A further includes a sensor 123 disposed between the inner center electrode 105 and the inner upper electrode 111. In some embodiments, the sensor 123 may be configured to detect the position of the substrate 150. In some embodiments, the sensor 123 may be configured to detect a distance between the sensor 123 and the substrate 150. In some embodiments, the sensor 123 may be a laser detector. In some embodiments, the inner center electrode 105 may include a hole to allow unimpeded transmissions of a laser beam. Although not shown in the figure, for the ones with ordinary skill in the art it is understandable that the etching system 100A may be also equipped with a plurality of pressure gauges, thickness monitor systems (quartz crystal monitor, spectroscopic ellipsometer, reflection high-energy electron diffraction detector (RHEED)), shutters, a rotational manipulator, viewports, transfer ports, etc.

FIG. 2B is a schematic view of a deposition system 100B in some embodiments, such as a physical vapor deposition (PVD) system. In some embodiments, the deposition system 100B may further include a power source 132. In some embodiments, the power source 132 may include a radio frequency (RF) power source and a respective matching circuit (both are not shown) operating at frequencies from a few tens of kilohertz (KHz) to tens of megahertz (MHz). In some embodiments, the deposition system 100B may further include a target 130 bonded on an electrode 131 (e.g. cathode). By applying a power on the electrode 131, plasma (i.e., a gas that contains ionized atoms or molecules) can be formed in a space in the chamber 101 near the target 130 in some embodiments. In some embodiments, technologies, such as for instance inductively coupled plasma, electron cyclotron resonance, microwave, and helicon wave can be integrated with the RF source for a creation of high-density discharges for desired deposition properties. In some embodiments, the deposition system 100B may be a DC magnetron sputtering system configured in a cathode target/anodic shield arrangement, wherein the electrode 131 and anode (not shown) are connected to a power source 132. In some embodiments, the target 130 and the electrode 131 may be cooled by a coolant running behind the target 130.

In some embodiments, the deposition system 100B may further include a power source 133, such as a RF power source, and the lower stage 102 may be coupled to a power source 133 in order to attract positively charged particles in the plasma bombarded off the surface of the target 130 by charged processing gas molecules (e.g., Ar t). In some embodiments, the back of the lower stage 102 may be coupled to electrical ground. By applying an AC voltage between the electrode 131 and the lower stage 102, the plasma may be formed on the target 130 and may extend across the space between the target 130 and the lower stage 102 to the surface of the substrate 150, in accordance with some embodiments. In some embodiments, the deposition system 100B may further include a temperature control unit 134 coupled to temperature control elements (not shown) on the lower stage 102 to control the temperature of the lower stage 102 and the substrate 150.

According to the exemplary embodiment described herein, the deposition system 100B can be used in processing the surface layers of the substrate 150. For example, any of a photoresist layer, mask layer, or other layer of a semiconductor wafer as desired, can be processed before or after an etch step, or any combination thereof, according to a specified recipe. The recipe also specifies parameters used to establish the proper environment in the chamber 101 for realizing the desired features and feature dimensions on the substrate 150. The recipe can specify a type of reactant gas to be introduced into the plasma chamber and its flow rate, a pressure during reaction, a power and frequency of the RF signal provided to the electrode 131 or the lower stage 102.

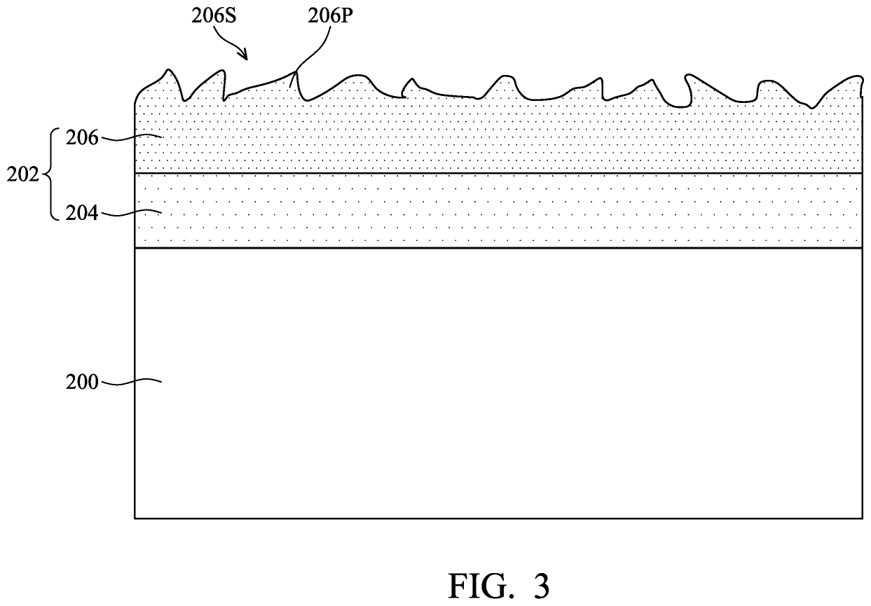

During the process, particle or defect issue may exist in the systems due to component material and/or coatings, which reduces component lifetime of the systems, in accordance with some embodiments of the present disclosure. To solve such issue, a protective structure 202 is provided (e.g. coated) on elements of the system 100, such as the elements of the chamber 101, the lower stage 102, and/or the upper stage 103, in accordance with some embodiments of the present disclosure. FIG. 3 shows detail of the protective structure 202 in some embodiments. In some embodiments, a substrate 200 is used to represent the surface of the elements of the chamber 101, the lower stage 102, and/or the upper stage 103. In some embodiments, the substrate 200 may include various materials, such as silicon or aluminum.

In some embodiments, the protective structure 202 may include a first protective layer 204 disposed on a surface of the substrate 200 and a second protective layer 206 disposed on the first protective layer 204. In some embodiments, the first protective layer 204 and the second protective layer 206 may be formed by atomic layer deposition. When comparing with protective structures formed by other techniques, such as air/suspension plasma spray (APS/SPS), aerosol deposition (AD), or electron beam-ion assisted deposition (EB-IAD) coating, the protective structure 202 formed by atomic layer deposition may have better purity, higher adhesive strength to the substrate 200, better plasma/radical erosion resistance, lower porosity (about 0%), and may be easier for microstructure and composition modification, in accordance with some embodiments of the present disclosure. Moreover, the protective structure 202 formed by atomic layer deposition may have lower probability to form particles or trace metals, in accordance with some embodiments of the present disclosure. Furthermore, the protective structure 202 formed by atomic layer deposition only needs deionized water for post cleaning, and any surface finish of the substrate 200 is applicable for atomic layer deposition, so the cost may be reduced, in accordance with some embodiments of the present disclosure.

In some embodiments, a cleaning process may be performed to the substrate 200 before forming the protective structure 202 on the substrate 200, such as an O₃ treatment. In some embodiments, the substrate 200 may be heated by being placed in an environment with predetermined temperature, such as between about 80° C. and about 600° C., between about 100° C. and about 500° C., about 200° C., about 300° C., or about 400° C.

In some embodiments, forming the first protective layer 204 of the protective structure 202 may include forming a first sub-protective layer with a first precursor and forming a second sub-protective layer with a second precursor. In some embodiments, the material of the first protective layer 204 may include Y₃Al₅O₁₂(YAG), Gd₃Al₅O₁₂, (Y,Gd)₃Al₅O₁₂, MgAl₂O₄, Al₂O₃, etc., or a combination thereof. In an embodiment that the first protective layer 204 includes Y₃Al₅O₁₂, the first precursor may include (CH₃)₃Al, and the second precursor may include Tris(methylcyclopentadienyl)yttrium(III) (Y(MeCp)₃). In some embodiments, an oxidation agent may be added during the cycle to oxidize the elements. In some embodiments, the oxidation agent may include H₂O.

In some embodiments, a super cycle of the atomic layer deposition when forming the first protective layer 204 may include forming alumina (i.e. first sub-protective layer) by (CH₃)₃Al for 1 to 6 cycles, followed forming yttria (i.e. second sub-protective layer) by Y(MeCp)₃ for 1 to 6 cycles. In some embodiments, the number of the cycles of forming the first sub-protective layer and the second sub-protective layer may be different, such as 3 cycles for forming the first sub-protective layer and 2 cycles for forming the second sub-protective layer. In some embodiments, the number of the cycles of forming alumina and yttria may be identical, depending on process requirement. In some embodiments, the super cycle may be performed for a plurality times until the thickness of the first protective layer 204 reaches a desired thickness, such as between about 5 nm and about 1 μm, or between about 10 nm to about 500 nm.

In some embodiments, in a super cycle for forming first protective layer 204 by atomic layer deposition, the first precursor may be temporarily stopped or pulsed for about 1 to about 5 seconds (e.g. 2, 3, or 4 seconds, etc.), followed by purge for about 5 to about 50 seconds (e.g. 22.2, 35.4, or 43.1 seconds, etc.). After, the oxidizer (e.g. H₂O) may be temporarily stopped or pulsed for about 1 to about 5 seconds (e.g. 2, 3, or 4 seconds, etc.), followed by purge for about 5 to about 60 seconds (e.g. 25, 35, or 40 seconds, etc.), in accordance with some embodiments of the present disclosure. Afterwards, the second precursor may be temporarily stopped or pulsed for about 0.5 to about 5 seconds (e.g. 0.8, 1.2, or 3 seconds, etc.), followed by purge for about 5 to about 30 seconds (e.g. 7.3, 9.8, or 15.1, 22.2 seconds, etc.). Finally, the oxidizer may be temporarily stopped or pulsed for about 0.5 to about 5 seconds (e.g. 0.7, 1, or 3.3 seconds, etc.), followed by purge for about 5 to about 40 seconds (e.g. 10, 20, or 30 seconds, etc.). Such process may be repeated for 1 to 6 times for a super cycle, in accordance with some embodiments of the present disclosure.

In some embodiments, the first protective layer 204 may be amorphous. In some embodiments, the first protective layer 204 may be conformally coated on the surface of the substrate 200, even for the substrate 200 having complicated shape. Moreover, the conformal first protective layer 204 is more flexible and thus relaxes the residual stress to increase the adhesive strength between the substrate 200 and the first protective layer 204 in accordance with some embodiments. In some embodiments, the first protective layer 204 may act as a diffusion stop layer to stop the diffusion of radicals generated during the process performed in the chamber 101, so the substrate 200 may be protected to increase the duration.

In some embodiments, forming the second protective layer 206 of the protective structure 202 may include forming a third sub-protective layer with a third precursor, followed by oxidizing the third sub-protective layer. In some embodiments, the material of the second protective layer 206 may include Y₂O₃, Gd₂O₃, Er₂O₃, and Yb₂O₃, etc., or a combination thereof. In an embodiment that the second protective layer 206 may include Y₂O₃, the third precursor may include Y(MeCp)₃. In some embodiments, an oxidation agent may be added during the cycle to oxidize the elements. In some embodiments, the oxidation agent may include H₂O.

In some embodiments, a super cycle of the atomic layer deposition when forming the second protective layer 206 may include forming yttria (i.e. third sub-protective layer) by Y(MeCp)₃. In some embodiments, the super cycle may be performed for a plurality times until the thickness of the second protective layer 206 reaches a desired thickness, such as between about 50 nm and 20 μm, or between about 100 nm to about 10 μm.

In some embodiments, in a super cycle for forming second protective layer 206 by atomic layer deposition, the third precursor may be temporarily stopped or pulsed for about 1 to about 5 seconds (e.g. 2, 3, or 4 seconds, etc.), followed by purge for about 5 to about 50 seconds (e.g. 22.2, 35.4, or 43.1 seconds, etc.). After, the oxidizer (e.g. H₂O) may be temporarily stopped or pulsed for about 1 to about 5 seconds (e.g. 2, 3, or 4 seconds, etc.), followed by purge for about 5 to about 60 seconds (e.g. 25, 35, or 40 seconds, etc.), in accordance with some embodiments of the present disclosure.

In some embodiments, the second protective layer 206 may be crystalline (e.g. cubic, tetragonal, hexagonal, rhombohedral, orthorhombic, monoclinic, triclinic, etc.), so the second protective layer 206 is harder and more resistant to ion bombardment, have high radical erosion resistance, and the defect on the interface between the first protective layer 204 and the second protective layer 206 may be reduced. In some embodiments, protrusions 206P may be formed on a surface 206S of the second protective layer 206, so that the surface 206S of the second protective layer 206 may have high micro-roughness (e.g. the protrusion 206p may have a height between 10 nm and 1000 nm and a width between 5 nm and 500 nm, and a ratio of the height of the protrusion 206P and the thickness of the second protective layer 206 is between 0.1 and 1), and the protrusions 206P on the surface 206S sticks the byproduct generated during the process performed in the system 100 to reduce the particles in the chamber 101, which may increase the yield of the semiconductor process. In some embodiments, the properties of the second protective layer 206 (including the protrusions 206P) depend from the preferred grain growth (e.g. (400) plane preferred orientation growth for Y₂O₃) of the material of the second protective layer 206, rather than depend from the material of the substrate 200. Therefore, the second protective layer 206 with desired surface roughness is applicable for different materials (e.g. Si, Al, etc.), in accordance with some embodiments of the present disclosure.

In some embodiments, before the units of the chamber 101 (e.g. the exhaust plate 108, the second casing 109, the third casing 110, the inner upper electrode 111, the separator 112, the outer upper electrode 113, the outer insulator 114, the first top element 115, the upper deposition element 116, and the second top element 117), the lower stage 102, and the upper stage 103 assembled with each other, the protective structure 202 is formed on at least one of these units to protect the units. After the protective structure 202 is formed, the units are then assembled with each other to form the system 100, in accordance with some embodiments of the present disclosure. Afterwards, the substrate 150 may be disposed on the lower stage 102 in the chamber 101, and then circuit layout may be formed on the substrate 150 in the chamber 101, in accordance with some embodiments of the present disclosure.

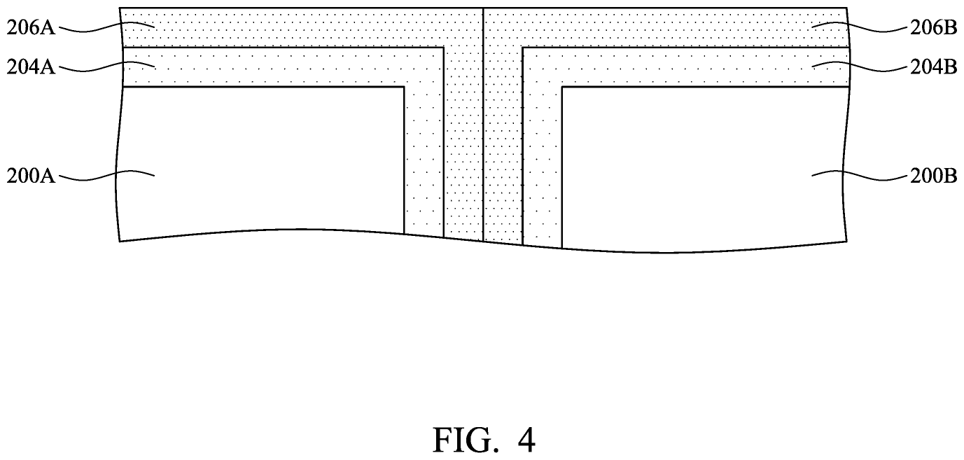

FIG. 4 is a schematic view when two units of the chamber 101 assembled with each other in some embodiments, such as two of the exhaust plate 108, the second casing 109, the third casing 110, the inner upper electrode 111, the separator 112, the outer upper electrode 113, the outer insulator 114, the first top element 115, the upper deposition element 116, and the second top element 117 that adjacent with each other. In some embodiments, the two units are respectively illustrated as a substrate 200A (or a first chamber unit) and a substrate 200B (or a second chamber unit) for simplicity. In some embodiments, a first protective layer 204A and a second protective layer 206A are formed on the substrate 200A, and a first protective layer 204B and a second protective layer 206B are formed on the substrate 200B. Therefore, the second protective layer 206A is in contact with the second protective layer 206B when the substrate 200A is assembled with the substrate 200B to form the system 100 (e.g. the chamber 101, the lower stage 102, or the upper stage 103), in accordance with some embodiments of the present disclosure. In some embodiments, the gap between the substrate 200A and the substrate 200B is filled by the first protective layer 204A, the second protective layer 206A, the first protective layer 204B, and the second protective layer 206B.

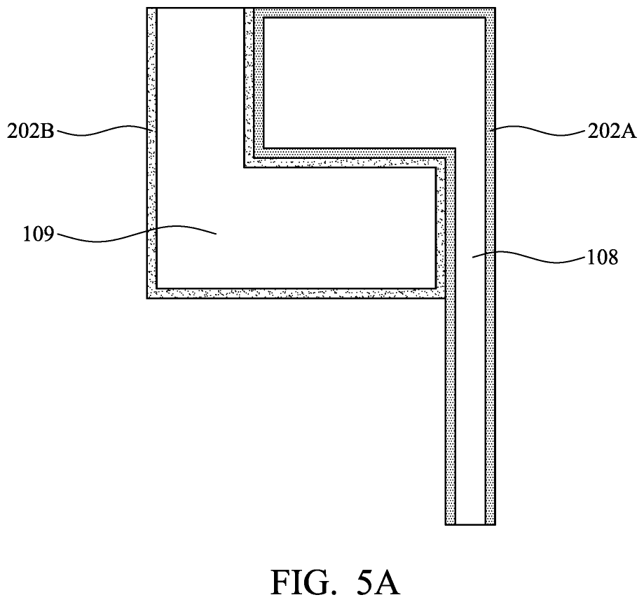

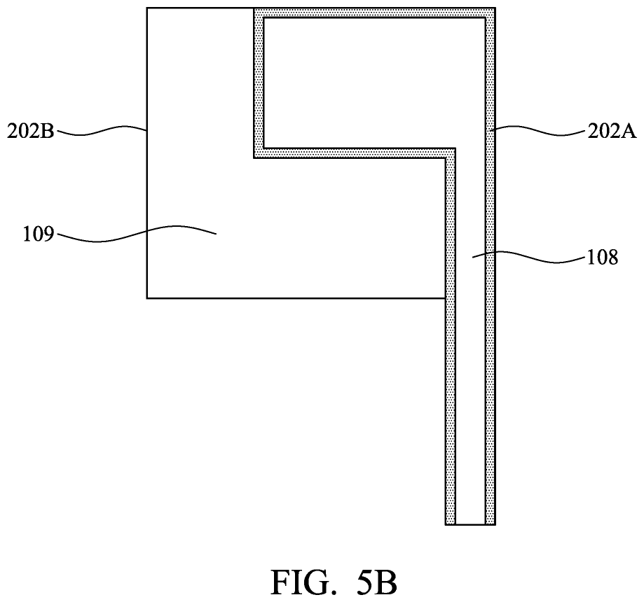

FIG. 5A is an enlarged view of a region 140 in FIG. 1, in accordance with some embodiments of the present disclosure, which shows the exhaust plate 108 and the second casing 109 as an example when two units of the system 100 assembled with each other. As shown in FIG. 5A, a protective structure 202A is formed on the exhaust plate 108 by atomic layer deposition, and a protective structure 202B is formed on the second casing 109 by atomic layer deposition, in accordance with some embodiments of the present disclosure. In some embodiments, the protective structure 202A is formed on opposite sides of the exhaust plate 108, and the protective structure 202B is formed on opposite sides of the second casing 109. Therefore, the protective structure 202A and the protective structure 202B may be formed inside the chamber 101 and outside the chamber 101 (i.e. exposed from the chamber 101), in accordance with some embodiments of the present disclosure.

In some embodiments, the protective structure 202 may be formed on certain units of the system 100, and some units of the system 100 may be free from the protective structure. For example, FIG. 5B is an enlarged view of a region 140 in FIG. 1, in accordance with some embodiments of the present disclosure, which shows the exhaust plate 108 and the second casing 109 as an example when two units of the system 100 assembled with each other. In this embodiment, the protective structure 202A is formed on opposite sides of the exhaust plate 108 by atomic layer deposition, and the second casing 109 is free from the protective structure 202 (i.e. free from the first protective layer 204 and the second protective layer 206). Therefore, the protective structure 202A on the exhaust plate 108 may be in direct contact with the second casing 109, in accordance with some embodiments of the present disclosure. In some embodiments, the protective structure 202 may be provides on the units that are closer to the lower stage 102.

In some embodiments, since the units closer to the lower stage 102 may face more attacks during the process (e.g. ion bombardment in PVD process). For example, in some embodiments, the protective structure 202 is provided on a first chamber unit (e.g. the exhaust plate 108), and a second chamber unit (e.g. the second casing 109) is free from the protective structure 202. In some embodiments, a distance between the first chamber unit and the lower stage 102 may be less than a distance between the second chamber unit and the lower stage 102 to further protect the units closer to the lower stage 102.

In summary, a system for processing a semiconductor device, a method for forming a semiconductor device, and a method for forming a protective structure on a chamber are provided in some embodiments of the present disclosure. The resulting chamber may have higher durability to withstand attacks during the process for forming the semiconductor device, and particles during the process may be reduced accordingly, thereby reduces the cost and increases the reliability.

A system for processing a semiconductor device is provided in some embodiments of the present disclosure. The system includes a chamber, a carrier disposed in the chamber and configured to holding a substrate, and a protective structure disposed on the chamber. The protective structure includes a first protective layer disposed on a surface of the chamber and a second protective layer disposed on the first protective layer. The first protective layer is amorphous. The second protective layer is crystalline.

A method for forming a semiconductor device is provided in some embodiments of the present disclosure. The method includes forming a first protective layer on a first chamber unit by atomic layer deposition, forming a second protective layer on the first protective layer on the first chamber unit by atomic layer deposition, assembling the first chamber unit and a second chamber unit to form a chamber, placing a substrate on a carrier in the chamber, and forming a circuit layout on the substrate in the chamber.

A method for forming a protective structure on a chamber is provided in some embodiments of the present disclosure. The method includes cleaning the chamber, heating the chamber, and forming a protective structure on the chamber. Forming a protective structure on the chamber includes depositing a first protective layer on a surface of the chamber by atomic layer deposition, and depositing a second protective layer on the first protective layer by atomic layer deposition. The protective structure is formed in the chamber and exposed from the chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system for processing a semiconductor device, comprising:
a chamber;
a carrier disposed in the chamber and configured to holding a substrate; and
a protective structure disposed on the chamber, comprising:
a first protective layer disposed on a surface of the chamber, wherein the first protective layer is amorphous; and
a second protective layer disposed on the first protective layer, wherein the second protective layer is crystalline.

2. The system as claimed in claim 1, wherein the protective structure is disposed in the chamber and exposed from the chamber.

3. The system as claimed in claim 1, wherein the protective structure is disposed on a first unit of the chamber, and a second unit is free from the protective structure.

4. The system as claimed in claim 1, wherein a thickness of the first protective layer is between 5 nm and 1 μm.

5. The system as claimed in claim 1, wherein a thickness of the second protective layer is between 50 nm and 20 μm.

6. The system as claimed in claim 1, wherein the first protective layer comprises Y₃Al₅O₁₂, Gd₃Al₅O₁₂, (Y,Gd)₃Al₅O₁₂, MgAl₂O₄, and Al₂O₃, and the second protective layer comprises Y₂O₃, Gd₂O₃, Er₂O₃, and Yb₂O₃.

7. A method for forming a semiconductor device, comprising:
forming a first protective layer on a first chamber unit by atomic layer deposition;
forming a second protective layer on the first protective layer on the first chamber unit by atomic layer deposition;
assembling the first chamber unit and a second chamber unit to form a chamber;
placing a substrate on a carrier in the chamber; and
forming a circuit layout on the substrate in the chamber.

8. The method as claimed in claim 7, wherein the second chamber unit is free from the first protective layer and the second protective layer.

9. The method as claimed in claim 8, wherein a distance between the first chamber unit and the carrier is less than a distance between the second chamber unit and the carrier.

10. The method as claimed in claim 7, further comprising:
forming the first protective layer on the second chamber unit by atomic layer deposition; and
forming the second protective layer on the first protective layer on the second chamber unit by atomic layer deposition.

11. The method as claimed in claim 10, wherein the second protective layer on the first chamber unit is in direct contact with the second protective layer on the first chamber unit.

12. The method as claimed in claim 7, wherein forming the first protective layer comprises alternately forming a first sub-protective layer with a first precursor and forming a second sub-protective layer with a second precursor, wherein the first precursor and the second precursor are different.

13. The method as claimed in claim 12, wherein times of forming the first sub-protective layer is greater than times of forming the second sub-protective layer.

14. The method as claimed in claim 12, wherein the first precursor comprises (CH₃)₃Al, and the second precursor comprises Y(MeCp)₃.

15. The method as claimed in claim 7, further comprising:
providing energy to a target in the chamber, thereby generating a plasma to the substrate.

16. A method for forming a protective structure on a chamber, comprising:
cleaning the chamber;
heating the chamber; and
forming a protective structure on the chamber, comprising:
depositing a first protective layer on a surface of the chamber by atomic layer deposition; and
depositing a second protective layer on the first protective layer by atomic layer deposition;
wherein the protective structure is formed in the chamber and exposed from the chamber.

17. The method as claimed in claim 16, wherein temperature of the chamber when heating the chamber is between 80° C. and 600° C.

18. The method as claimed in claim 16, wherein the first protective layer is amorphous, and the second protective layer is crystalline.

19. The method as claimed in claim 16, wherein depositing the first protective layer comprises alternately forming a first sub-protective layer with a first precursor and forming a second sub-protective layer with a second precursor, and depositing the second protective layer comprises forming a third sub-protective layer with a third precursor, wherein the first protective layer and the second protective layer comprises different material, and the second precursor and the third precursor comprise an identical material.

20. The method as claimed in claim 19, wherein depositing the first protective layer further comprises temporarily stopping the deposition between forming the first sub-protective layer and forming the second sub-protective layer, wherein duration of the stopping is greater than duration of forming the first sub-protective layer or duration of forming the second sub-protective layer.
